(19) United States
(12) Patent Application Publication
(10) Pub. No.: US 2015/0357501 A1
(43) Pub. Date: Dec. 10, 2015

(54) FOUR JUNCTION INVERTED METAMORPHIC SOLAR CELL

(71) Applicant: SolAero Technologies Corp., Albuquerque, NM (US)

(72) Inventors: Daniel DERKACS, Albuquerque, NM (US); Mark STAN, Albuquerque, NM (US)

(21) Appl. No.: 14/828,197

(22) Filed: Aug. 17, 2015

Related U.S. Application Data
(63) Continuation-in-part of application No. 13/872,663, filed on Apr. 29, 2013.
Application No. 13/872,663 is a continuation-in-part of application No. 12/337,043, filed on Dec. 17, 2008, now abandoned.
(60) Provisional application No. 62/158,415, filed on May 7, 2015.

(51) Int. Cl. H01L 31/0687; H01L 31/0304; H01L 31/18; H01L 31/065

(52) U.S. Cl. CPC H01L 31/06875; H01L 31/065; H01L 31/03046; H01L 31/1892; H01L 31/1844

(57) ABSTRACT

A multijunction solar cell which includes: an upper first solar subcell having a first band gap; a second solar subcell adjacent to said upper first solar subcell and having a second band gap smaller than said first band gap; a third solar subcell adjacent to said second solar subcell and having a third band gap smaller than said second band gap; a graded interlayer adjacent to said third solar subcell, said graded interlayer having a fourth band gap greater than said third band gap; and a lower fourth solar subcell adjacent to said graded interlayer, said lower fourth solar subcell having a fifth band gap smaller than said third band gap such that said lower fourth solar subcell is lattice mismatched with respect to said third solar subcell.

### REFERENCE TO RELATED APPLICATIONS

This application is a continuation-in-part of U.S. patent application Ser. No. 13/872,663 filed Apr. 29, 2013, which in turn is a continuation-in-part of U.S. patent application Ser. No. 12/337,043, filed Dec. 17, 2008, which are incorporated herein by reference in their entirety.

This application claims the benefit of U.S. Provisional Application No. 62/158,415, filed May 7, 2015, which is incorporated herein by reference in its entirety.

This application is related to co-pending U.S. patent application Ser. No. 14/660,092, filed Mar. 17, 2015, which is a divisional of U.S. patent application Ser. No. 12/716,814, filed Mar. 3, 2010, now U.S. Pat. No. 9,018,521, which in turn was a continuation-in-part of U.S. patent application Ser. No. 12/337,043, filed Dec. 17, 2008, which are incorporated herein by reference in their entirety.

This application may also be related to U.S. patent application Ser. No. 12/389,053, filed Feb. 19, 2009; U.S. patent application Ser. No. 12/367,991, filed Feb. 9, 2009; U.S. patent application Ser. Nos. 12/362,201, 12/362,213, and 12/362,225, filed Jan. 29, 2009; U.S. patent application Ser. No. 12/337,014, filed Dec. 17, 2008; U.S. patent application Ser. No. 12/267,812, filed Nov. 10, 2008; U.S. patent application Ser. No. 12/258,190, filed Oct. 24, 2008; U.S. patent application Ser. No. 12/253,051, filed Oct. 16, 2008; U.S. patent application Ser. No. 12/190,449, filed Aug. 12, 2008; U.S. patent application Ser. No. 12/187,477, filed Aug. 7, 2008; U.S. patent application Ser. No. 12/218,582, filed Jul. 16, 2008; U.S. patent application Ser. No. 12/218,558, filed Jul. 16, 2008; U.S. patent application Ser. No. 12/123,864, filed May 20, 2008; U.S. patent application Ser. No. 12/102,550, filed Apr. 14, 2008; U.S. patent application Ser. Nos. 12/047,842 and 12/047,944, filed Mar. 13, 2008; U.S. patent application Ser. No. 12/023,772, filed Jan. 31, 2008; U.S. patent application Ser. No. 11/956,069, filed Dec. 13, 2007; U.S. patent application Ser. Nos. 11/860,142 and 11/860,183, filed Sep. 24, 2007; U.S. patent application Ser. No. 11/836,402, filed Aug. 9, 2007; U.S. patent application Ser. No. 11/616,596, filed Dec. 27, 2006; U.S. patent application Ser. No. 11/614,332, filed Dec. 21, 2006; U.S. patent application Ser. No. 11/445,793, filed Jun. 2, 2006; and U.S. patent application Ser. No. 11/500,053, filed Aug. 7, 2006, each of which may be incorporated by reference in their entireties.

This application is also related to U.S. patent application Ser. No. ______ (Attorney Docket No. B008) filed simultaneously herewith.

### BACKGROUND

1. Field

The present disclosure relates to the field of semiconductor devices, and to fabrication processes and devices such as multijunction solar cells based on III-V semiconductor compounds including a metamorphic layer. Such devices are also known as inverted metamorphic multijunction solar cells.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

Typical III-V compound semiconductor solar cells are fabricated on a semiconductor wafer in vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

Inverted metamorphic solar cell structures based on III-V compound semiconductor layers, such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), present an important conceptual starting point for the development of future commercial high efficiency solar cells. However, the materials and structures for a number of different layers of the cell proposed and described in such reference present a number of practical difficulties relating to the appropriate choice of materials and fabrication steps.

Improving the efficiency of space-grade solar cells has been the goal of researchers for decades. Efficiency of space-grade solar cells has improved from 23% (for a dual junction InGaP/GaAs on inactive Ge) to 29.5% (for a triple junction InGaP/InGaAs/Ge solar cell), which not only been realized through improved material quality, but also through improved cell designs that reduce power degradation from charged particle radiation that is characteristic of the space operating environment.

### SUMMARY

In one aspect, the present disclosure provides a multijunction solar cell. In one embodiment, the multijunction solar cell comprises: an upper first solar subcell having a first band gap; a second solar subcell adjacent to said upper first solar subcell and having a second band gap smaller than said first band gap; a third solar subcell adjacent to said second solar subcell and having a third band gap smaller than said second band gap; a graded interlayer adjacent to said third solar subcell, said graded interlayer having a fourth band gap greater than said third band gap; and a lower fourth solar subcell adjacent to said graded interlayer, said lower fourth solar subcell having a fifth band gap smaller than said third band gap such that said lower fourth solar subcell is lattice mismatched with respect to said third solar subcell.

In another aspect, the present disclosure provides a method of manufacturing a solar cell. In one embodiment, the method comprises: providing a first substrate; depositing on the first substrate a first sequence of layers of semiconductor material forming a first solar subcell, a second solar subcell, and a third solar subcell; depositing on said third solar subcell a grading interlayer; depositing on said grading interlayer a second sequence of layers of semiconductor material forming a fourth solar subcell, the fourth solar subcell being lattice mismatched to the third solar subcell; mounting and bonding a surrogate substrate on top of the sequence of layers; and removing the first substrate.

In one or more embodiments, the graded interlayer may be compositionally graded to lattice match the third solar subcell on one side and the fourth solar subcell on the other side.

In one or more embodiments, the graded interlayer may be composed of any of the As, P, N, Sb based III-V compound semiconductors subject to the constraints of having the in-plane lattice parameter greater than or equal to that of the third solar subcell and less than or equal to that of the fourth solar subcell, and may have a band gap energy greater than that of the third solar subcell and of the fourth solar subcell.

In one or more embodiments, the graded interlayer may be composed of (InₓGa₁₋ₓ)_{y}Al_{1-y}As with 0<x<1, 0<y<1, and x and y selected such that the band gap remains constant throughout its thickness.

In one or more embodiments, the band gap of the graded interlayer may remain at a constant value in the range of 1.42 to 1.60 eV throughout its thickness.

In one or more embodiments, the band gap of the graded interlayer may remain constant at a value in the range of 1.5 to 1.6 eV.

In one or more embodiments, the upper first subcell may be composed of an AlInGaP or InGaP emitter layer and an AlInGaP base layer, the second subcell may be composed of InGaP emitter layer and a AlGaAs base layer, the third subcell may be composed of an InGaP or GaAs emitter layer and an GaAs base layer, and the bottom fourth subcell may be composed of an InGaAs base layer and an InGaAs emitter layer lattice matched to the base.

In one or more embodiments, the fourth solar subcell may have a band gap in the range of approximately 1.05 to 1.15 eV, the third solar subcell may have a band gap in the range of approximately 1.40 to 1.42 eV, the second solar subcell may have a band gap in the range of approximately 1.65 to 1.78 eV and the first solar subcell may have a band gap in the range of 1.92 to 2.2 eV.

In one or more embodiments, the fourth solar subcell may have a band gap of approximately 1.10 eV, the third solar subcell may have a band gap in the range of 1.40-1.42 eV, the second solar subcell may have a band gap of approximately 1.73 eV and the first solar subcell may have a band gap of approximately 2.10 eV.

In one or more embodiments, the first solar subcell may be composed of AlGaInP, the second solar subcell may be composed of an InGaP emitter layer and a AlGaAs base layer, the third solar subcell may be composed of GaAs or InGaAs (with the value of x in Inₓ between 0 and 1%), and the fourth solar subcell may be composed of InGaAs.

In one or more embodiments, each of the second subcell and the upper first subcell comprise aluminum in addition to semiconductor elements.

In one or more embodiments, each of the second subcell and the upper first subcell comprise aluminum in such quantity so that the average band gap of all four subcells is greater than 1.44 eV.

In one or more embodiments, the selection of the composition of the subcells and their band gaps maximizes the efficiency of the solar cell at a predetermined high temperature value (in the range of 50 to 70 degrees Centigrade) in deployment in space at AM0 at a predetermined time after the beginning of life (BOL), such predetermined time being referred to as the end-of-life (EOL) time.

In one or more embodiments, the selection of the composition of the subcells and their band gaps maximizes the efficiency of the solar cell at a predetermined high temperature value (in the range of 50 to 70 degrees Centigrade) not at initial deployment, but after continuous deployment of the solar cell in space at AM0 at a predetermined time after the initial deployment, such time being at least one year, with the average band gap of all four cells being greater than 1.44 eV.

In one or more embodiments, the predetermined time after the initial deployment is at least two years.

In some embodiments, the predetermined time is at least two years.

In some embodiments, the predetermined time is at least five years.

In some embodiments, the predetermined time is at least ten years.

In some embodiments, the predetermined time is at least twelve years.

In some embodiments, the predetermined time is at least fifteen years.

In one or more embodiments, the selection of the composition of the subcells and their band gaps maximizes the efficiency of the solar cell at a predetermined high temperature value (in the range of 50 to 70 degrees Centigrade) not at initial deployment, but after continuous deployment of the solar cell in space at AM0 at a predetermined time after the initial deployment, such time being at least x years, where x is in the range of 1 to 20, with the average band gap of all four cells being greater than 1.44 eV.

In some embodiments, additional layer(s) may be added or deleted in the cell structure without departing from the scope of the present disclosure.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teaching herein will recognize additional applications, modifications and embodiments in other fields, which are within the scope of the disclosure as disclosed and claimed herein and with respect to which the disclosure could be of utility.

### BRIEF DESCRIPTION OF THE DRAWING

The apparatus and methods described herein will be better and more fully appreciated by reference to the following detailed description when considered in conjunction with the accompanying drawings, wherein:

FIG. 1 is a cross-sectional view of a solar cell after an initial stage of fabrication including the deposition of certain semiconductor layers on the growth substrate;

FIG. 2A is a cross-sectional view of a first embodiment of the solar cell of FIG. 1 that includes one distributed Bragg reflector (DBR) layer after the next sequence of process steps;

FIG. 2B is a cross-sectional view of a second embodiment of the solar cell of FIG. 1 that includes one distributed Bragg reflector (DBR) layer after the next sequence of process steps;

FIG. 3A is a cross-sectional view of a first embodiment of the solar cell of FIG. 1 that includes two distributed Bragg reflector (DBR) layers after the next sequence of process steps; and

FIG. 3B is a cross-sectional view of a second embodiment of the solar cell of FIG. 1 that includes two distributed Bragg reflector (DBR) layers after the next sequence of process steps.

### GLOSSARY OF TERMS

“III-V compound semiconductor” refers to a compound semiconductor formed using at least one elements from group III of the periodic table and at least one element from group V of the periodic table. III-V compound semiconductors include binary, tertiary and quaternary compounds. Group III includes boron (B), aluminum (Al), gallium (Ga), indium (In) and thallium (T). Group V includes nitrogen (N), phosphorus (P), arsenic (As), antimony (Sb) and bismuth (Bi).

“Band gap” refers to an energy difference (e.g., in electron volts (eV)) separating the top of the valence band and the bottom of the conduction band of a semiconductor material.

“Beginning of Life (BOL)” refers to the time at which a photovoltaic power system is initially deployed in operation.

“Compound semiconductor” refers to a semiconductor formed using two or more chemical elements.

“End of Life (EOL)”, refers to a predetermined time or times after the Beginning of Life, during which the photovoltaic power system has been deployed and has been operational. The EOL time or times may, for example, be specified by the customer as part of the required technical performance specifications of the photovoltaic power system to allow the solar cell designer to define the solar cell subcells and sublayer compositions of the solar cell to meet the technical performance requirement at the specified time or times, in addition to other design objectives. The terminology “EOL” is not meant to suggest that the photovoltaic power system is not operational or does not produce power after the EOL time.

“Graded interlayer” (or “grading interlayer”)—see “metamorphic layer”.

“Inverted metamorphic multijunction solar cell” or “IMM solar cell” refers to a solar cell in which the subcells are deposited or grown on a substrate in a “reverse” sequence such that the higher band gap subcells, which would normally be the “top” subcells facing the solar radiation in the final deployment configuration, are deposited or grown on a growth substrate prior to depositing or growing the lower band gap subcells.

“Layer” refers to a relatively planar sheet or thickness of semiconductor or other material. The layer may be deposited or grown, e.g., by epitaxial or other techniques.

“Lattice mismatched” refers to two adjacently disposed materials having different lattice constants from one another.

“Metamorphic layer” or “graded interlayer” refers to a layer that achieves a gradual transition in lattice constant generally throughout its thickness in a semiconductor structure.

### DESCRIPTION OF THE PREFERRED EMBODIMENTS

Details of the present disclosure will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

A 33% efficient quadruple junction InGaP₂/GaAs/In_{0.30}Ga_{0.70}As/In_{0.60}Ga_{0.40}As (with band gaps 1.91 eV/1.42 eV/1.03 eV/0.70 eV, respectively) inverted metamorphic multijunction cell may be 10% (relative) more efficient at beginning of life (BOL) than standard ZTJ triple junction devices and have 40% lower mass when permanently bonded to a 150 um thick low-mass rigid substrate. Further, inverted metamorphic technology may extend the choice of materials that can be integrated together by making possible simultaneous realization of high quality materials that are both lattice-matched to the substrate (InGaP and GaAs, grown first) and lattice-mismatched (In_{0.30}Ga_{0.70}As and In_{0.60}Ga_{0.40}As). The advantage of a metamorphic approach may be that a wide range of infrared bandgaps may be accessed via InGaAs subcells grown atop optically transparent step graded buffer layers. Further, metamorphic materials may offer near-perfect quantum efficiencies, favorably low E_{g}-V_{oc} offsets, and high efficiencies. As may often be the case though, efficiency gains may rarely materialize without additional costs. For example, a quadruple junction inverted metamorphic multijunction cell may be more costly than a ZTJ due to thicker epitaxy and more complicated processing. Further, an inverted epitaxial foil may be removed from the growth substrate and temporarily or permanently bonded to a rigid substrate right-side-up to complete frontside processing. Still further, the result may be an all-top-contact cell that may be largely indistinguishable from a traditional ZTJ solar cell. Yet despite the quadruple junction inverted metamorphic multijunction cell being a higher efficiency, lower mass drop-in replacement for ZTJ, the higher specific cost [$/Watt] may discourage customers from adopting new or changing cell technologies.

The inverted metamorphic quadruple junction AlInGaP/AlGaAs/GaAs/InGaAs (with band gaps 2.1 eV/1.73 eV/1.42 eV/1.10 eV respectively) solar cell, according to the present disclosure, is not a design that agrees with the conventional wisdom in that an optimized multijunction cell should have balanced photocurrent generation among all subcells and use the entire solar spectrum including the infrared spectrum from 1200 nm-2000 nm. In this disclosure, a high bandgap current-matched triple junction stack may be grown first followed by a lattice-mismatched 1.10 eV InGaAs subcell, which in one embodiment, forms the “bottom” subcell. The inverted InGaAs subcell is subsequently removed from the growth substrate and bonded to a rigid carrier so that the four junction solar cell can then be processed as a normal solar cell.

Despite the beginning of life (BOL) efficiency being lower than the traditional inverted metamorphic quadruple junction solar cell, when high temperature end of life (hereinafter referred to as “HT-EOL”) $/W is used as the design metric, the proposed structure may provide a 10% increase in HT-EOL power and a significant decrease in HT-EOL $/W.

The proposed technology differs from existing art (e.g., U.S. Pat. No. 8,969,712 B2) in that a four junction device is constructed using three lattice-matched subcells and one lattice-mismatched subcell. Previous inverted metamorphic quadruple junction solar cells devices were constructed using two lattice-matched subcells and two lattice mismatched subcells. As a result, the cost of the epitaxy of the proposed architecture may be cheaper as the cell, e.g., may use a thinner top cell reducing In and P usage, may reduce the number of graded buffer layers to one from two, and may eliminate the need for a high In content bottom cell, which may be expensive due to the quantity of In required.

The basic concept of fabricating an inverted metamorphic multijunction (IMM) solar cell is to grow the subcells of the solar cell on a substrate in a “reverse” sequence. That is, the high band gap subcells (i.e. subcells with band gaps in the range of 1.9 to 2.3 eV), which would normally be the “top” subcells facing the solar radiation, are grown epitaxially on a semiconductor growth substrate, such as for example GaAs or Ge, and such subcells are therefore lattice-matched to such substrate. One or more lower band gap middle subcells (i.e. with band gaps in the range of 1.3 to 1.9 eV) can then be grown on the high band gap subcells.

At least one lower subcell is formed over the middle subcell such that the at least one lower subcell is substantially lattice-mismatched with respect to the growth substrate and such that the at least one lower subcell has a third lower band gap (e.g., a band gap in the range of 0.8 to 1.2 eV). A surrogate substrate or support structure is then attached or provided over the “bottom” or substantially lattice-mismatched lower subcell, and the growth semiconductor substrate is subsequently removed. (The growth substrate may then subsequently be re-used for the growth of a second and subsequent solar cells).

A variety of different features of inverted metamorphic multijunction solar cells are disclosed in the related applications noted above. Some or all of such features may be included in the structures and processes associated with the solar cells of the present disclosure. However, more particularly, the present disclosure is directed to the fabrication of a four junction inverted metamorphic solar cell using two different metamorphic layers, all grown on a single growth substrate. In the present disclosure, the resulting construction includes four subcells, with band gaps in the range of 1.92 to 2.2 eV (e.g., 2.10 eV), 1.65 to 1.78 eV (e.g., 1.73 eV), 1.42 to 1.50 eV (e.g., 1.42 eV), and 1.05 to 1.15 eV (e.g., 1.10 eV), respectively.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

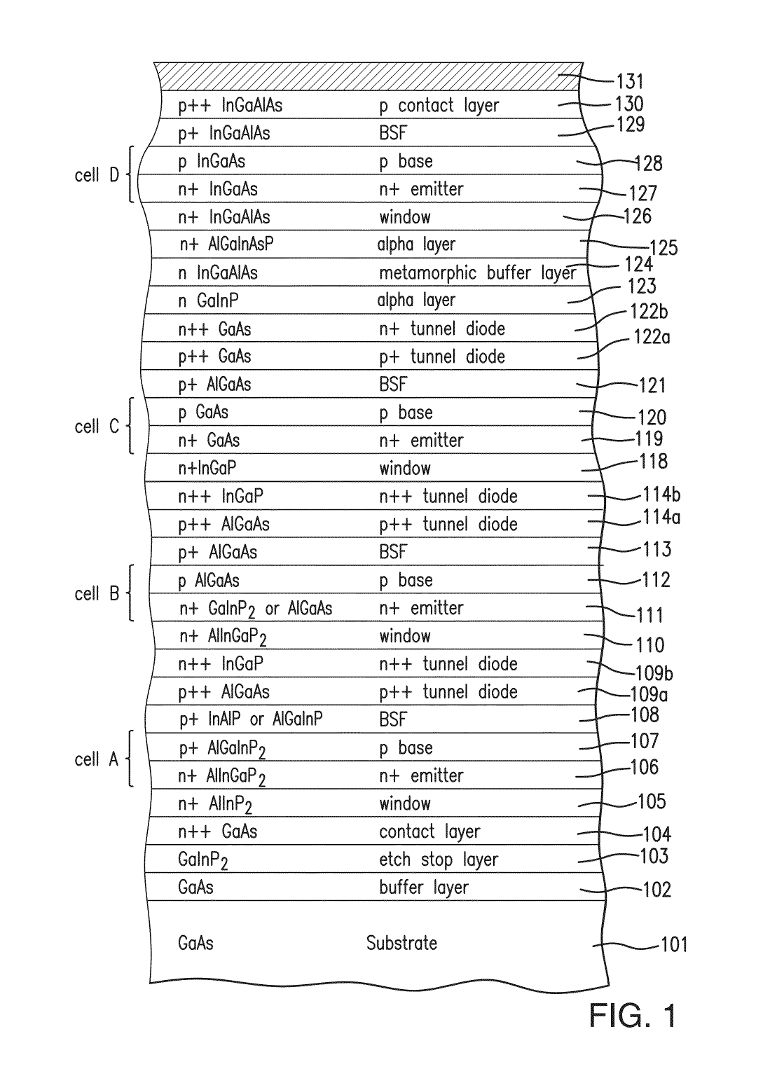

FIG. 1 depicts the multijunction solar cell according to the present disclosure after the sequential formation of the four subcells A, B, C and D on a GaAs growth substrate. More particularly, there is shown a growth substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane, as more fully described in U.S. Patent Application Pub. No. 2009/0229662 A1 (Stan et al.).

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

In one embodiment, the emitter layer 106 is composed of InGa(Al)P₂ and the base layer 107 is composed of InGa(Al)P₂. The aluminum or Al term in parenthesis in the preceding formula means that Al is an optional constituent, and in this instance may be used in an amount ranging from 0% to 40%.

Subcell A will ultimately become the “top” subcell of the inverted metamorphic structure after completion of the process steps according to the present disclosure to be described hereinafter.

On top of the base layer 107 a back surface field (“BSF”) layer 108 preferably p+AlGaInP is deposited and used to reduce recombination loss.

The BSF layer 108 drives minority carriers from the region near the base/BSF interface surface to minimize the effect of recombination loss. In other words, a BSF layer 108 reduces recombination loss at the backside of the solar subcell A and thereby reduces the recombination in the base.

On top of the BSF layer 108 is deposited a sequence of heavily doped p-type and n-type layers 109a and 109b that forms a tunnel diode, i.e., an ohmic circuit element that connects subcell A to subcell B. Layer 109a is preferably composed of p++AlGaAs, and layer 109b is preferably composed of n++InGaP.

A window layer 110 is deposited on top of the tunnel diode layers 109a/109b, and is preferably n+InGaP. The advantage of utilizing InGaP as the material constituent of the window layer 110 is that it has an index of refraction that closely matches the adjacent emitter layer 111, as more fully described in U.S. Patent Application Pub. No. 2009/0272430 A1 (Cornfeld et al.). The window layer 110 used in the subcell B also operates to reduce the interface recombination loss. It should be apparent to one skilled in the art, that additional layer(s) may be added or deleted in the cell structure without departing from the scope of the present disclosure.

On top of the window layer 110 the layers of subcell B are deposited: the n-type emitter layer 111 and the p-type base layer 112. These layers are preferably composed of InGaP and AlinGaAs respectively (for a Ge substrate or growth template), or InGaP and AlGaAs respectively (for a GaAs substrate), although any other suitable materials consistent with lattice constant and bandgap requirements may be used as well. Thus, subcell B may be composed of a GaAs, InGaP, AlGaInAs, AlGaAsSb, GaInAsP, or AlGaInAsP, emitter region and a GaAs, InGaP, AlGaInAs, AlGaAsSb, GaInAsP, or AlGaInAsP base region.

In previously disclosed implementations of an inverted metamorphic solar cell, the second subcell or subcell B or was a homostructure. In the present disclosure, similarly to the structure disclosed in U.S. Patent Application Pub. No. 2009/0078310 A1 (Stan et al.), the second subcell or subcell B becomes a heterostructure with an InGaP emitter and its window is converted from InAlP to AlInGaP. This modification reduces the refractive index discontinuity at the window/emitter interface of the second subcell, as more fully described in U.S. Patent Application Pub. No. 2009/0272430 A1 (Cornfeld et al.). Moreover, the window layer 110 is preferably is doped three times that of the emitter 111 to move the Fermi level up closer to the conduction band and therefore create band bending at the window/emitter interface which results in constraining the minority carriers to the emitter layer.

On top of the cell B is deposited a BSF layer 113 which performs the same function as the BSF layer 109. The p++/n++ tunnel diode layers 114a and 114b respectively are deposited over the BSF layer 113, similar to the layers 109a and 109b, forming an ohmic circuit element to connect subcell B to subcell C. The layer 114a is preferably composed of p++AlGaAs, and layer 114b is preferably composed of n++InGaP.

A window layer 118 preferably composed of n+ type GaInP is then deposited over the tunnel diode layer 114. This window layer operates to reduce the recombination loss in subcell “C”. It should be apparent to one skilled in the art that additional layers may be added or deleted in the cell structure without departing from the scope of the present disclosure.

On top of the window layer 118, the layers of cell C are deposited: the n+ emitter layer 119, and the p-type base layer 120. These layers are preferably composed of n+ type GaAs and n+ type GaAs respectively, or n+ type InGaP and p type GaAs for a heterojunction subcell, although another suitable materials consistent with lattice constant and bandgap requirements may be used as well.

In some embodiments, subcell C may be (In)GaAs with a band gap between 1.40 eV and 1.42 eV. Grown in this manner, the cell has the same lattice constant as GaAs but has a low percentage of Indium 0%<In<1% to slightly lower the band gap of the subcell without causing it to relax and create dislocations. In this case, the subcell remains lattice matched, albeit strained, and has a lower band gap than GaAs. This helps improve the subcell short circuit current slightly and improve the efficiency of the overall solar cell.

In some embodiments, the third subcell or subcell C may have quantum wells or quantum dots that effectively lower the band gap of the subcell to approximately 1.3 eV. All other band gap ranges of the other subcells described above remain the same. In such embodiment, the third subcell is still lattice matched to the GaAs substrate. Quantum wells are typically “strain balanced” by incorporating lower band gap or larger lattice constant InGaAs (e.g. a band gap of ˜1.3 eV) and higher band gap or smaller lattice constant GaAsP. The larger/smaller atomic lattices/layers of epitaxy balance the strain and keep the material lattice matched.

A BSF layer 121, preferably composed of InGaAlAs, is then deposited on top of the cell C, the BSF layer performing the same function as the BSF layers 108 and 113.

The p++/n++ tunnel diode layers 122a and 122b respectively are deposited over the BSF layer 121, similar to the layers 114a and 114b, forming an ohmic circuit element to connect subcell C to subcell D. The layer 122a is preferably composed of p++GaAs, and layer 122b is preferably composed of n++GaAs.

An alpha layer 123, preferably composed of n-type GaInP, is deposited over the tunnel diode 122a/122b, to a thickness of about 1.0 micron. Such an alpha layer is intended to prevent threading dislocations from propagating, either opposite to the direction of growth into the top and middle subcells A, B and C, or in the direction of growth into the subcell D, and is more particularly described in U.S. Patent Application Pub. No. 2009/0078309 A1 (Cornfeld et al.).

A metamorphic layer (or graded interlayer) 124 is deposited over the alpha layer 123 using a surfactant. Layer 124 is preferably a compositionally step-graded series of InGaAlAs layers, preferably with monotonically changing lattice constant, so as to achieve a gradual transition in lattice constant in the semiconductor structure from subcell C to subcell D while minimizing threading dislocations from occurring. The band gap of layer 124 is constant throughout its thickness, preferably approximately equal to 1.5 to 1.6 eV, or otherwise consistent with a value slightly greater than the band gap of the middle subcell C. One embodiment of the graded interlayer may also be expressed as being composed of (InₓGa₁₋ₓ)_{y} Al_{1-y}As, with x and y selected such that the band gap of the interlayer remains constant at approximately 1.5 to 1.6 eV or other appropriate band gap.

In the surfactant assisted growth of the metamorphic layer 124, a suitable chemical element is introduced into the reactor during the growth of layer 124 to improve the surface characteristics of the layer. In the preferred embodiment, such element may be a dopant or donor atom such as selenium (Se) or tellurium (Te). Small amounts of Se or Te are therefore incorporated in the metamorphic layer 124, and remain in the finished solar cell. Although Se or Te are the preferred n-type dopant atoms, other non-isoelectronic surfactants may be used as well.

Surfactant assisted growth results in a much smoother or planarized surface. Since the surface topography affects the bulk properties of the semiconductor material as it grows and the layer becomes thicker, the use of the surfactants minimizes threading dislocations in the active regions, and therefore improves overall solar cell efficiency.

As an alternative to the use of non-isoelectronic one may use an isoelectronic surfactant. The term “isoelectronic” refers to surfactants such as antimony (Sb) or bismuth (Bi), since such elements have the same number of valence electrons as the P atom of InGaP, or the As atom in InGaAlAs, in the metamorphic buffer layer. Such Sb or Bi surfactants will not typically be incorporated into the metamorphic layer 124.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present disclosure, the layer 124 is composed of a plurality of layers of InGaAlAs, with monotonically changing lattice constant, each layer having the same band gap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present disclosure utilizes a plurality of layers of InGaAlAs for the metamorphic layer 124 for reasons of manufacturability and radiation transparency, other embodiments of the present disclosure may utilize different material systems to achieve a change in lattice constant from subcell C to subcell D. Thus, the system of Wanlass using compositionally graded InGaP is a second embodiment of the present disclosure. Other embodiments of the present disclosure may utilize continuously graded, as opposed to step graded, materials. More generally, the graded interlayer may be composed of any of the As, P, N, Sb based III-V compound semiconductors subject to the constraints of having the in-plane lattice parameter greater than or equal to that of the second solar cell and less than or equal to that of the third solar cell, and having a bandgap energy greater than that of the second solar cell.

An alpha layer 125, preferably composed of n+ type AlGaInAsP, is deposited over metamorphic buffer layer 124, to a thickness of about 1.0 micron. Such an alpha layer is intended to prevent threading dislocations from propagating, either opposite to the direction of growth into the top and middle subcells A, B and C, or in the direction of growth into the subcell D, and is more particularly described in U.S. Patent Application Pub. No. 2009/0078309 A1 (Cornfeld et al.).

A window layer 126 preferably composed of n+ type InGaAlAs is then deposited over alpha layer 125. This window layer operates to reduce the recombination loss in the fourth subcell “D”. It should be apparent to one skilled in the art that additional layers may be added or deleted in the cell structure without departing from the scope of the present disclosure.

On top of the window layer 126, the layers of cell D are deposited: the n+ emitter layer 127, and the p-type base layer 128. These layers are preferably composed of n+ type InGaAs and p type InGaAs respectively, or n+ type InGaP and p type InGaAs for a heterojunction subcell, although another suitable materials consistent with lattice constant and bandgap requirements may be used as well.

A BSF layer 129, preferably composed of p+ type InGaAlAs, is then deposited on top of the cell D, the BSF layer performing the same function as the BSF layers 108, 113 and 121.

A high band gap contact layer 130, preferably composed of p++ type InGaAlAs, is deposited on the BSF layer 129.

The composition of this contact layer 130 located at the bottom (non-illuminated) side of the lowest band gap photovoltaic cell (i.e., subcell “D” in the depicted embodiment) in a multijunction photovoltaic cell, can be formulated to reduce absorption of the light that passes through the cell, so that (i) the backside ohmic metal contact layer below it (on the non-illuminated side) will also act as a mirror layer, and (ii) the contact layer doesn't have to be selectively etched off, to prevent absorption.

A metal contact layer 131 is deposited over the p semiconductor contact layer 130. The metal is preferably the sequence of metal layers Ti/Au/Ag/Au.

Also, the metal contact scheme chosen is one that has a planar interface with the semiconductor, after heat treatment to activate the ohmic contact. This is done so that (1) a dielectric layer separating the metal from the semiconductor doesn't have to be deposited and selectively etched in the metal contact areas; and (2) the contact layer is specularly reflective over the wavelength range of interest.

Optionally, an adhesive layer (e.g., Wafer Bond, manufactured by Brewer Science, Inc. of Rolla, Mo.) can be deposited over the metal layer 131, and a surrogate substrate can be attached. In some embodiments, the surrogate substrate may be sapphire. In other embodiments, the surrogate substrate may be GaAs, Ge or Si, or other suitable material. The surrogate substrate can be about 40 mils in thickness, and can be perforated with holes about 1 mm in diameter, spaced 4 mm apart, to aid in subsequent removal of the adhesive and the substrate. As an alternative to using an adhesive layer, a suitable substrate (e.g., GaAs) may be eutectically or permanently bonded to the metal layer 131.

Optionally, the original substrate can be removed by a sequence of lapping and/or etching steps in which the substrate 101, and the buffer layer 102 are removed. The choice of a particular etchant is growth substrate dependent.

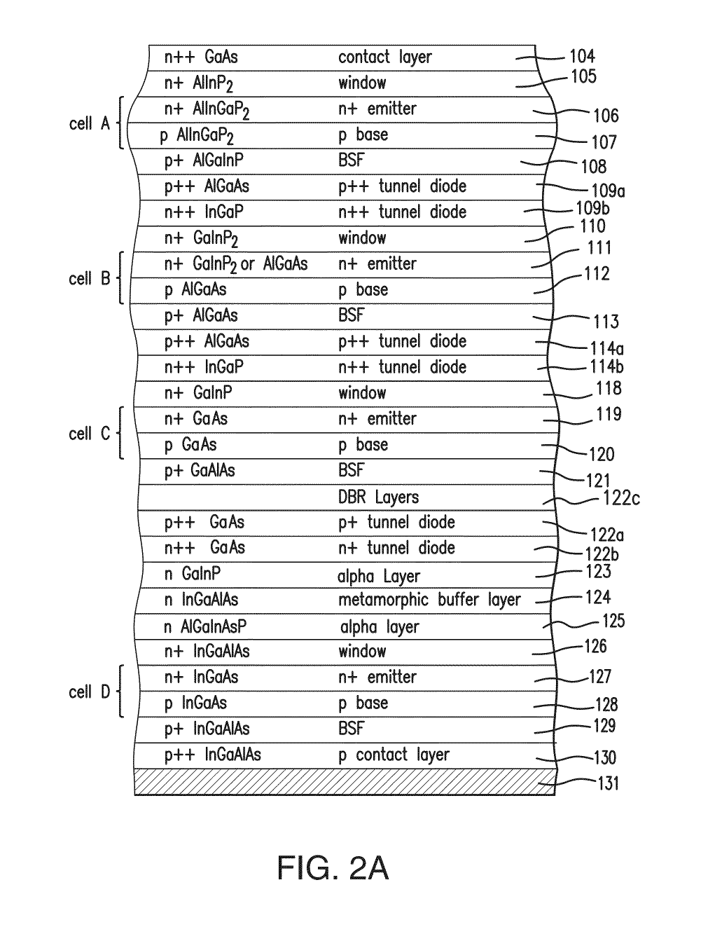

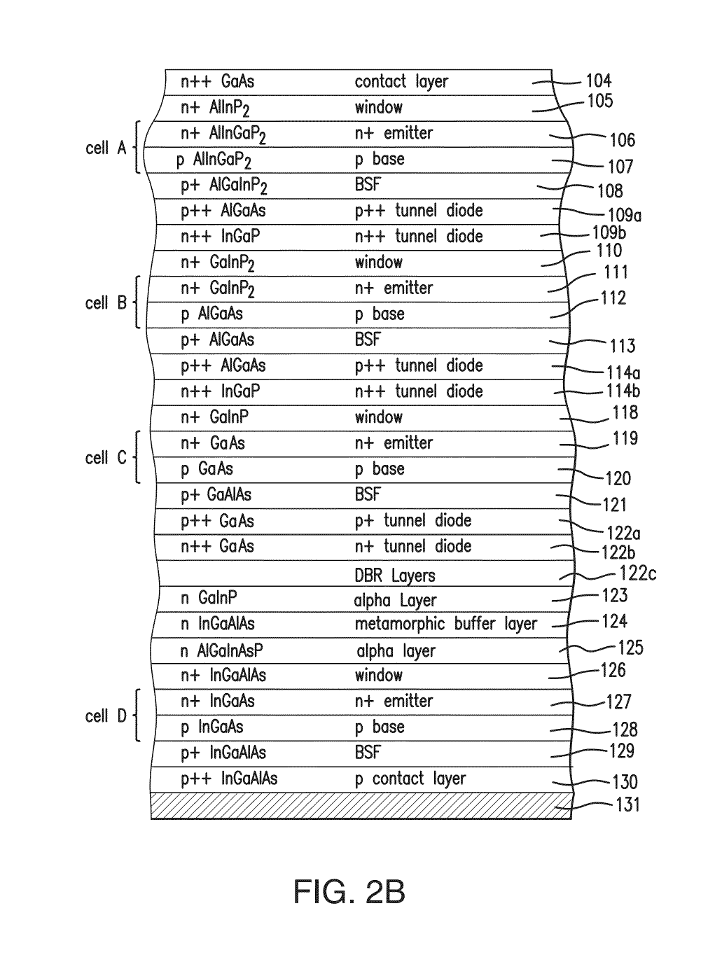

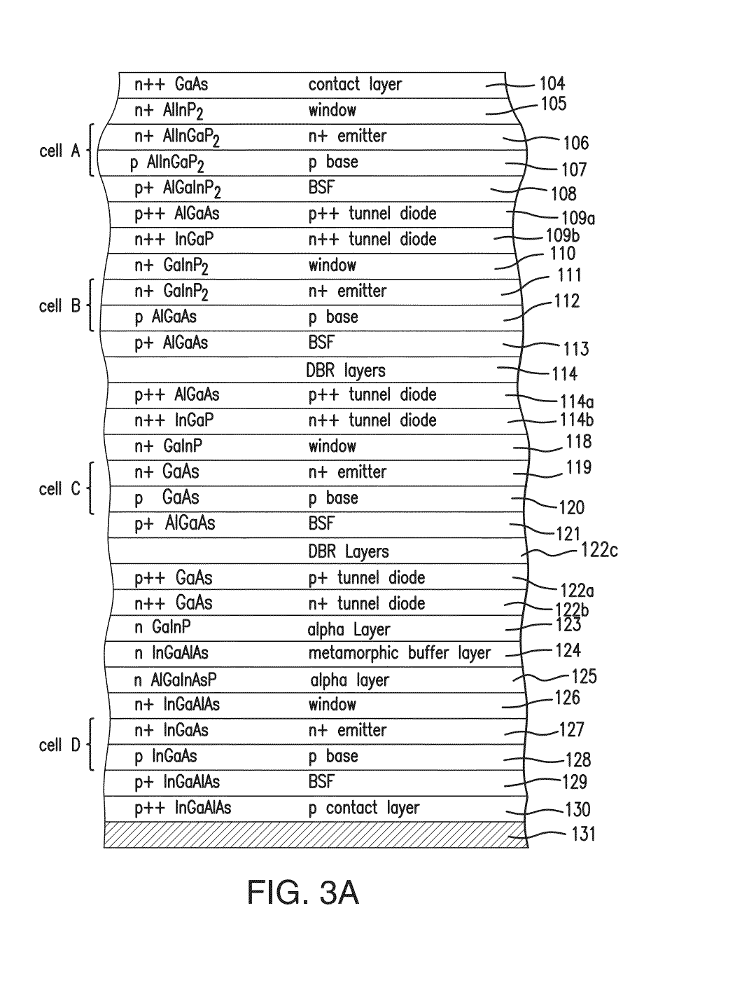

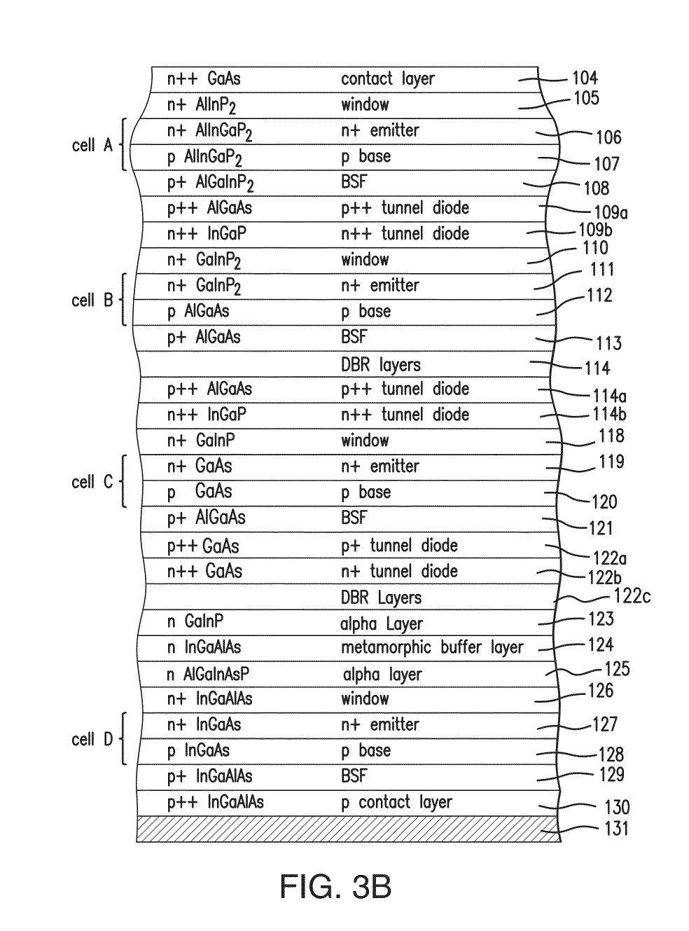

FIGS. 2A, 2B, 3A, and 3B are cross-sectional views of embodiments of solar cells similar to that in FIG. 1, with the orientation with the metal contact layer 131 being at the bottom of the Figure and with the original substrate having been removed. In addition, the etch stop layer 103 has been removed, for example, by using a HCl/H₂O solution.

It should be apparent to one skilled in the art, that additional layer(s) may be added or deleted in the cell structure without departing from the scope of the present disclosure. For example, one or more distributed Bragg reflector (DBR) layers can be added for various embodiments of the present invention.

FIGS. 2A and 2B are cross-sectional views of embodiments of a solar cell similar to that of FIG. 1 that includes distributed Bragg reflector (DBR) layers 122c.

FIG. 2A is a cross-sectional view of a first embodiment of a solar cell similar to that of FIG. 1 that includes distributed Bragg reflector (DBR) layers 122c adjacent to and between the third solar subcell C and the graded interlayer 124 and arranged so that light can enter and pass through the third solar subcell C and at least a portion of which can be reflected back into the third solar subcell C by the DBR layers 122c. In FIG. 2A, the distributed Bragg reflector (DBR) layers 122c are specifically located between the third solar subcell C and tunnel diode layers 122a/122b.

FIG. 2B is a cross-sectional view of a second embodiment of a solar cell similar to that of FIG. 1 that includes distributed Bragg reflector (DBR) layers 122c adjacent to and between the third solar subcell C and the graded interlayer 124 and arranged so that light can enter and pass through the third solar subcell C and at least a portion of which can be reflected back into the third solar subcell C by the DBR layers 122c. In FIG. 2B, the distributed Bragg reflector (DBR) layers 122c are specifically located between tunnel diode layers 122a/122b and graded interlayer 124.

FIGS. 3A and 3B are cross-sectional views of embodiments of a solar cell similar to that of FIG. 1 that include distributed Bragg reflector (DBR) layers 114 in addition to the distributed Bragg reflector layers 122c described in FIGS. 2A and 2B.

FIG. 3A is a cross-sectional view of a first embodiment of a solar cell similar to that of FIG. 1 that includes, in addition to the distributed Bragg reflector layers 122c described in FIGS. 2A and 2B, distributed Bragg reflector (DBR) layers 114 adjacent to and between the second solar subcell B and the third solar subcell C and arranged so that light can enter and pass through the second solar subcell B and at least a portion of which can be reflected back into the second solar subcell B by the DBR layers 114. In FIG. 3A, the distributed Bragg reflector (DBR) layers 114 are specifically located between the second solar subcell and tunnel diode layers 114a/114b; and the distributed Bragg reflector (DBR) layers 122c are specifically located between the third solar subcell C and tunnel diode layers 122a/122b.

FIG. 3B is a cross-sectional view of a second embodiment of a solar cell similar to that of FIG. 1 that includes, in addition to the distributed Bragg reflector layers 122c described in FIGS. 2A and 2B, distributed Bragg reflector (DBR) layers 114 adjacent to and between the second solar subcell B and the third solar subcell C and arranged so that light can enter and pass through the second solar subcell B and at least a portion of which can be reflected back into the second solar subcell B by the DBR layers 114. In FIG. 3B, the distributed Bragg reflector (DBR) layers 114 are specifically located between the second solar subcell and tunnel diode layers 114a/114b; and the distributed Bragg reflector (DBR) layers 122c are specifically located between tunnel diode layers 122a/122b and graded interlayer 124.

For some embodiments, distributed Bragg reflector (DBR) layers 114 and/or 122c can be composed of a plurality of alternating layers of lattice matched materials with discontinuities in their respective indices of refraction. For certain embodiments, the difference in refractive indices between alternating layers is maximized in order to minimize the number of periods required to achieve a given reflectivity, and the thickness and refractive index of each period determines the stop band and its limiting wavelength.

For some embodiments, distributed Bragg reflector (DBR) layers 114 and/or 122c includes a first DBR layer composed of a plurality of p type AlₓGa₁₋ₓAs layers, and a second DBR layer disposed over the first DBR layer and composed of a plurality of p type Al_{y}Ga_{1-y}As layers, where y is greater than x, and 0<x<1, 0<y<1.

The present disclosure provides an inverted metamorphic multijunction solar cell that follows a design rule that one should incorporate as many high bandgap subcells as possible to achieve the goal to increase high temperature EOL performance. For example, high bandgap subcells may retain a greater percentage of cell voltage as temperature increases, thereby offering lower power loss as temperature increases. As a result, both HT-BOL and HT-EOL performance of the exemplary inverted metamorphic multijunction solar cell may be expected to be greater than traditional cells.

For example, the cell efficiency (%) measured at room temperature (RT) 28° C. and high temperature (HT) 70° C., at beginning of life (BOL) and end of life (EOL), for a standard three junction commercial solar cell (ZTJ) is as follows:

| Condition | Efficiency | |
|---|---|---|
| BOL 28° C. | 29.1% | |
| BOL 70° C. | 26.4% | |
| EOL 70° C. | 23.4% | After 5E14 e/cm² radiation |
| EOL 70° C. | 22.0% | After 1E15 e/cm² radiation |

For the IMMX solar cell described in the present disclosure, the corresponding data is as follows:

| Condition | Efficiency | |
|---|---|---|
| BOL 28° C. | 29.5% | |
| BOL 70° C. | 26.6% | |
| EOL 70° C. | 24.7% | After 5E14 e/cm² radiation |
| EOL 70° C. | 24.2% | After 1E15 e/cm² radiation |

One should note the slightly higher cell efficiency of the IMMX solar cell than the standard commercial solar cell (ZTJ) at BOL both at 28° C. and 70° C. However, the IMMX solar cell described in the present disclosure exhibits substantially improved cell efficiency (%) over the standard commercial solar cell (ZTJ) at 1 MeV electron equivalent fluence of 5×10¹⁴ e/cm², and dramatically improved cell efficiency (%) over the standard commercial solar cell (ZTJ) at 1 MeV electron equivalent fluence of 1×10¹⁵ e/cm².

A low earth orbit (LEO) satellite will typically experience radiation equivalent to 5×10¹⁴ e/cm² over a five year lifetime. A geosynchronous earth orbit (GEO) satellite will typically experience radiation in the range of 5×10¹⁴ e/cm² to 1×10 e/cm² over a fifteen year lifetime.

The wide range of electron and proton energies present in the space environment necessitates a method of describing the effects of various types of radiation in terms of a radiation environment which can be produced under laboratory conditions. The methods for estimating solar cell degradation in space are based on the techniques described by Brown et al. [Brown, W. L., J. D. Gabbe, and W. Rosenzweig, Results of the Telstar Radiation Experiments, Bell System Technical J., 42, 1505, 1963] and Tada [Tada, H. Y., J. R. Carter, Jr., B. E. Anspaugh, and R. G. Downing, Solar Cell Radiation Handbook, Third Edition, JPL Publication 82-69, 1982]. In summary, the omnidirectional space radiation is converted to a damage equivalent unidirectional fluence at a normalised energy and in terms of a specific radiation particle. This equivalent fluence will produce the same damage as that produced by omnidirectional space radiation considered when the relative damage coefficient (RDC) is properly defined to allow the conversion. The relative damage coefficients (RDCs) of a particular solar cell structure are measured a priori under many energy and fluence levels in addition to different coverglass thickness values. When the equivalent fluence is determined for a given space environment, the parameter degradation can be evaluated in the laboratory by irradiating the solar cell with the calculated fluence level of unidirectional normally incident flux. The equivalent fluence is normally expressed in terms of 1 MeV electrons or 10 MeV protons.

The software package Spenvis (www.spenvis.oma.be) is used to calculate the specific electron and proton fluence that a solar cell is exposed to during a specific satellite mission as defined by the duration, altitude, azimuth, etc. Spenvis employs the EQFLUX program, developed by the Jet Propulsion Laboratory (JPL) to calculate 1 MeV and 10 MeV damage equivalent electron and proton fluences, respectively, for exposure to the fluences predicted by the trapped radiation and solar proton models for a specified mission environment duration. The conversion to damage equivalent fluences is based on the relative damage coefficients determined for multijunction cells [Marvin, D. C., Assessment of Multijunction Solar Cell Performance in Radiation Environments, Aerospace Report No. TOR-2000 (1210)-1, 2000]. New cell structures eventually need new RDC measurements as different materials can be more or less damage resistant than materials used in conventional solar cells. A widely accepted total mission equivalent fluence for a geosynchronous satellite mission of 15 year duration is 1 MeV 1×10¹⁵ electrons/cm².

The exemplary solar cell described herein may require the use of aluminum in the semiconductor composition of each of the top two subcells. Aluminum incorporation is widely known in the III-V compound semiconductor industry to degrade BOL subcell performance due to deep level donor defects, higher doping compensation, shorter minority carrier lifetimes, and lower cell voltage and an increased BOL E_{g}-V_{oc} metric. In short, increased BOL E_{g}-V_{oc} may be the most problematic shortcoming of aluminum containing subcells; the other limitations can be mitigated by modifying the doping schedule or thinning base thicknesses.

Furthermore, at BOL, it is widely accepted that great subcells have a room temperature E_{g}-V_{oc} of approximately 0.40. A wide variation in BOL E_{g}-V_{oc} may exist for subcells of interest to IMMX cells. However, Applicants have found that inspecting E_{g}-V_{oc} at HT-EOL may reveal that aluminum containing subcells perform no worse than other materials used in III-V solar cells. For example, all of the subcells at EOL, regardless of aluminum concentration or degree of lattice-mismatch, have been shown to display a nearly-fixed E_{g}-V_{oc} of approximately 0.6 at room temperature 28° C.

The exemplary inverted metamorphic multijunction solar cell design philosophy may be described as opposing conventional cell efficiency improvement paths that employ infrared subcells that increase in expense as the bandgap of the materials decreases. For example, proper current matching among all subcells that span the entire solar spectrum is often a normal design goal. Further, known approaches—including dilute nitrides grown by MBE, upright metamorphic, and inverted metamorphic multijunction solar cell designs—may add significant cost to the cell and only marginally improve HT-EOL performance. Still further, lower HT-EOL $/W may be achieved when inexpensive high bandgap subcells are incorporated into the cell architecture, rather than more expensive infrared subcells. The key to enabling the exemplary solar cell design philosophy described herein is the observation that aluminum containing subcells perform well at HT-EOL.

It will be understood that each of the elements described above, or two or more together, also may find a useful application in other types of constructions differing from the types of constructions described above.

Although the preferred embodiment of the present disclosure utilizes a vertical stack of four subcells, the present disclosure can apply to stacks with fewer or greater number of subcells, i.e. two junction cells, three junction cells, five junction cells, six junction cells, etc.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present disclosure may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type AlInGaP is one example of a homojunction subcell. Alternatively, as more particularly described in U.S. Patent Application Pub. No. 2009/0078310 A1 (Stan et al.), the present disclosure may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present disclosure.

While the disclosure has been illustrated and described as embodied in an inverted metamorphic multijunction solar cell, it is not intended to be limited to the details shown, since various modifications and structural changes may be made without departing in any way from the spirit of the present disclosure.

Thus, while the description of this disclosure has focused primarily on solar cells or photovoltaic devices, persons skilled in the art know that other optoelectronic devices, such as, thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this disclosure also applies to photodetectors and LEDs with structures, compositions of matter, articles of manufacture, and improvements as described above for photovoltaic cells.

Without further analysis, the foregoing will so fully reveal the gist of the present disclosure that others can, by applying current knowledge, readily adapt it for various applications without omitting features that, from the standpoint of prior art, fairly constitute essential characteristics of the generic or specific aspects of this disclosure and, therefore, such adaptations should and are intended to be comprehended within the meaning and range of equivalence of the following claims.

1. A multijunction solar cell comprising:
an upper first solar subcell having a first band gap;
a second solar subcell adjacent to said upper first solar subcell and having a second band gap smaller than said first band gap;
a third solar subcell adjacent to said second solar subcell and having a third band gap smaller than said second band gap;
a graded interlayer adjacent to said third solar subcell, said second graded interlayer having a fourth band gap greater than said third band gap; and
a lower fourth solar subcell adjacent to said graded interlayer, said lower fourth solar subcell having a fifth band gap smaller than said third band gap such that said lower fourth solar subcell is lattice mismatched with respect to said third solar subcell.

2. The multijunction solar cell as defined in claim 1, wherein the lower fourth solar subcell has a band gap in the range of approximately 1.05 to 1.15 eV, the third solar subcell has a band gap in the range of approximately 1.40 to 1.50 eV, the second solar subcell has a band gap in the range of approximately 1.65 to 1.78 eV and the upper first solar subcell has a band gap in the range of approximately 1.92 to 2.2 eV.

3. The multijunction solar cell as defined in claim 2, wherein the lower fourth solar subcell has a band gap of approximately 1.10 eV, the third solar subcell has a band gap in the range of 1.40 to 1.42 eV, the second solar subcell has a band gap of approximately 1.73 eV and the upper first solar subcell has a band gap of approximately 2.10 eV.

4. The multijunction solar cell as defined in claim 1, wherein the selection of the composition of the subcells and their band gaps maximizes the efficiency of the solar cell at a predetermined high temperature value (in the range of 50 to 70 degrees Centigrade) in deployment in space at AM0 at a predetermined time after the initial deployment in space, or the “beginning of life (BOL)”, such predetermined time being referred to as the “end-of-life (EOL)” time, and being at least one year.

5. The multijunction solar cell as defined in claim 1, wherein the graded interlayer is compositionally graded to lattice match the third solar subcell on one side and the lower fourth solar subcell on the other side, and is composed of any of the As, P, N, Sb based III-V compound semiconductors subject to the constraints of having the in-plane lattice parameter greater than or equal to that of the third solar subcell and less than or equal to that of the lower fourth solar subcell, and having a band gap energy greater than that of the third solar subcell and the fourth solar subcell.

6. The multijunction solar cell as defined in claim 1, wherein the graded interlayer is composed of (InₓGa₁₋ₓ)_{y}Al_{1-y}As with 0<x<1, 0<y<1, and x and y selected such that the band gap remains constant throughout its thickness.

7. The multijunction solar cell as defined in claim 1, wherein the band gap of the graded interlayer remains at a constant value in the range of 1.42 to 1.60 eV throughout its thickness.

8. The multijunction solar cell as defined in claim 1, wherein the upper first solar subcell is composed of AlGaInP, the second solar subcell is composed of an InGaP emitter layer and a AlGaAs base layer, the third solar subcell is composed of GaAs, and the lower fourth solar subcell is composed of InGaAs.

9. The multijunction solar cell as defined in claim 1, further comprising:
a distributed Bragg reflector (DBR) layer adjacent to and between the second and the third solar subcells and arranged so that light can enter and pass through the second solar subcell and at least a portion of which can be reflected back into the second solar subcell by the DBR layer.

10. The multijunction solar cell as defined in claim 1, further comprising:
a distributed Bragg reflector (DBR) layer adjacent to and between the third solar subcell and the graded interlayer and arranged so that light can enter and pass through the third solar subcell and at least a portion of which can be reflected back into the third solar subcell by the DBR layer.

11. The multijunction solar cell as defined in claim 9, wherein the distributed Bragg reflector layer is composed of a plurality of alternating layers of lattice matched materials with discontinuities in their respective indices of refraction.

12. The multijunction solar cell as defined in claim 11, wherein the difference in refractive indices between alternating layers is maximized in order to minimize the number of periods required to achieve a given reflectivity, and the thickness and refractive index of each period determines the stop band and its limiting wavelength.

13. The multijunction solar cell as defined in claim 12, wherein the DBR layer includes a first DBR layer composed of a plurality of p type AlₓGa₁₋ₓAs layers, and a second DBR layer disposed over the first DBR layer and composed of a plurality of p type Al_{y}Ga_{1-y}As layers, where y is greater than x.

14. The multijunction solar cell as defined in claim 10, wherein the distributed Bragg reflector layer is composed of a plurality of alternating layers of lattice matched materials with discontinuities in their respective indices of refraction.

15. The multijunction solar cell as defined in claim 14, wherein the difference in refractive indices between alternating layers in maximized in order to minimize the number of periods required to achieve a given reflectivity, and the thickness and refractive index of each period determines the stop band and its limiting wavelength.

16. The multijunction solar cell as defined in claim 15, wherein the DBR layer includes a first DBR layer composed of a plurality of p type AlₓGa₁₋ₓAs layers, and a second DBR layer disposed over the first DBR layer and composed of a plurality of p type Al_{y}Ga_{1-y}As layers, where y is greater than x.

17. A method of manufacturing a solar cell comprising:
providing a first substrate;
depositing on the first substrate a first sequence of layers of semiconductor material forming a first solar subcell, a second solar subcell, and a third solar subcell;
depositing on said third solar subcell a grading interlayer;
depositing on said grading interlayer a second sequence of layers of semiconductor material forming a fourth solar subcell, the fourth solar subcell being lattice mismatched to the third solar subcell;
mounting and bonding a surrogate substrate on top of the sequence of layers; and
removing the first substrate.

18. The method as defined in claim 17, wherein the fourth solar subcell has a band gap in the range of approximately 1.05 to 1.15 eV, the third solar subcell has a band gap in the range of approximately 1.40 to 1.50 eV, the second solar subcell has a band gap in the range of approximately 1.65 to 1.78 eV and the first solar subcell has a band gap in the range of 1.92 to 2.2 eV, and wherein the graded interlayer is composed of (InₓGa₁₋ₓ)_{y}Al_{1-y}As with 0<x<1, 0<y<1, and x and y selected such that the band gap remains constant throughout its thickness, and the band gap of the graded interlayer remains at a constant value in the range of 1.42 to 1.60 eV throughout its thickness.

19. The method as defined in claim 17, wherein the first solar subcell is composed of AlGaInP, the second solar subcell is composed of an InGaP emitter layer and a AlGaAs base layer, the third solar subcell is composed of GaAs or InGaAs (with 0<x<0.01), and the fourth solar subcell is composed of InGaAs.

20. The method as defined in claim 17, wherein the third solar subcell includes quantum wells or quantum dots so that the band gap of the third solar subcell is approximately 1.3 eV.
